(19) United States
(12) Patent Application Publication
(10) Pub. No.: US 2009/0322408 A1
(43) Pub. Date: Dec. 31, 2009

(54) METHOD FOR REDUCING SWITCHING POWER LOSS

(76) Inventors: Allen Y. Tan, Taipei City (TW); H.P. Yee, Taipei City (TW)

Correspondence Address: SINORICA, LLC, 2275 Research Blvd., Suite 500, ROCKVILLE, MD, 20850, US

(21) Appl. No.: 12/146,504

(22) Filed: Jun. 26, 2008

(51) Int. Cl. H03K 17/687

(52) U.S. Cl. 327/427

(57) ABSTRACT

A method of controlling a switch in a power converter in order to reduce switching power loss is disclosed. A trigger voltage level is set and the voltage level across the switch V_{DS} is measured. If the voltage level of V_{DS} is lower than the trigger voltage level the slope of V_{DS} is determined. If the slope is less than zero the switch is turned on and the trigger voltage is lowered. If the slope is zero the switch is turned on and the trigger voltage stays the same. A timer is used to ensure the slope will approach zero. If the slope is positive the switch is turned on, the trigger voltage is raised, and the timer is told to turn on earlier. By repeated adjusting the trigger voltage level the slope approaches zero and maximum power loss reduction is achieved.

### BACKGROUND OF THE INVENTION

1. Field of the Invention

The present invention relates to quasi resonant pulse width modulation. More specifically, the present invention discloses a method for reducing and minimizing switching power loss in a pulse width modulation controller.

2. Description of the Prior Art

Power converters have transformers with primary and secondary windings in order to provide isolation. A switch such as a transistor is electrically coupled to the primary winding of the transformer. The switch controls the voltage transferring from the primary to the secondary winding. However, power loss occurs when the switch operates.

Refer to FIG. 1A, which is a schematic diagram illustrating a portion of a power converter circuit of the prior art and to FIG. 1B, which is a diagram illustrating voltages in the circuit of FIG. 1A.

The circuit 100 includes a transformer 110 having a primary winding PW and a secondary winding SW and a transistor 120 connected to the primary winding PW. An input voltage V_{IN} is applied to the primary winding PW. A voltage V_{G} is periodically applied (T_{ON}) to the gate of the transistor 120 to control the transfer of power from the primary winding PW to the secondary winding SW. When the transistor 120 turns on energy is stored in the transformer 110. As the transistor 120 turns off the stored energy in the transformer 110 is discharged.

A reflected voltage V_{R} is generated when the transistor 120 turns off. As a result the voltage V_{DS} across the transistor 120 equals the input voltage V_{IN} plus the reflected voltage V_{R}. While the transistor 120 is turned off a parasitic capacitor inherent in the transistor 120 stores the energy from the voltage V_{D}.

After a discharge period T_{DS} the energy of the transformer 110 is fully discharge and the energy stored in the parasitic capacitor flows back to the input voltage V_{IN} through the primary winding PW of the transformer 110.

The primary winding PW and the parasitic capacitor create a resonant tank with a resonant frequency f_{R}. While resonating, energy flows back and forth between the primary winding PW and the parasitic capacitor.

An ideal time to turn on the transistor 120 is when the lowest voltage level occurs after a delay time T_{low} in order to reduce power loss to a minimum.

Therefore there is need for a more effective method of controlling the switching device in order to reduce switching power loss.

### SUMMARY OF THE INVENTION

To achieve these and other advantages and in order to overcome the disadvantages of the conventional method in accordance with the purpose of the invention as embodied and broadly described herein, the present invention provides a method of controlling a switching device in a power converter circuit which reduces switching power loss.

The method of the present invention comprises determining the slope of the V_{DS} voltage. When the slope is zero or is approximately zero the switch is turned on. The slope of the V_{DS} voltage approaches zero at its lowest level during the resonating period. This is shown after the delay time T_{low} shown in FIG. 1B.

The present invention also sets a trigger voltage level. The trigger voltage level is a threshold level that V_{DS} must drop below before the step of determining the slope starts.

Once the voltage level of V_{DS} drops below the trigger voltage level the method of the present invention measures a first voltage level of V_{DS} after a period of time a second voltage level of V_{DS} is measured. The slope of the V_{DS} voltage is determined by subtracting the first voltage level from the second voltage level and dividing by the time between the first measurement and the second measurement. If the slope is approximately or equal to zero the switch is turned on. If the slope is greater than zero another voltage measurement is made and the slope is determined again until the slope is less than or equal to zero. This slope is compared with a previous slope or previous slopes that have been stored in a memory. If a slope transition of approximately zero slope is detected, the switch is turned on.

The time duration of the present invention is a percentage of the time duration of the previous slope. If the slope is negative the trigger voltage level is lowered. If the slope is zero the voltage level of the trigger voltage level is kept the same. If the slope is positive or the timer times out the trigger voltage level is raised and the timer is told to turn on earlier. This allows the method of the present invention to fine tune and detect the lowest voltage level of V_{DS}.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1A is a schematic diagram illustrating a portion of a power converter circuit of the prior art;

FIG. 1B is a diagram illustrating voltages in the circuit of FIG. 1A; and

FIG. 2A is a flowchart illustrating a method for reducing switching power loss according to an embodiment of the present invention;

FIG. 2B is a drawing illustrating voltage waveforms resulting from the method of FIG. 2A;

FIGS. 3-9 are flowcharts illustrating methods for reducing switching power loss according to embodiments of the present invention; and

FIG. 10 is a diagram illustrating an implementation of a switching power loss reduction method according to an embodiment of the present invention.

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

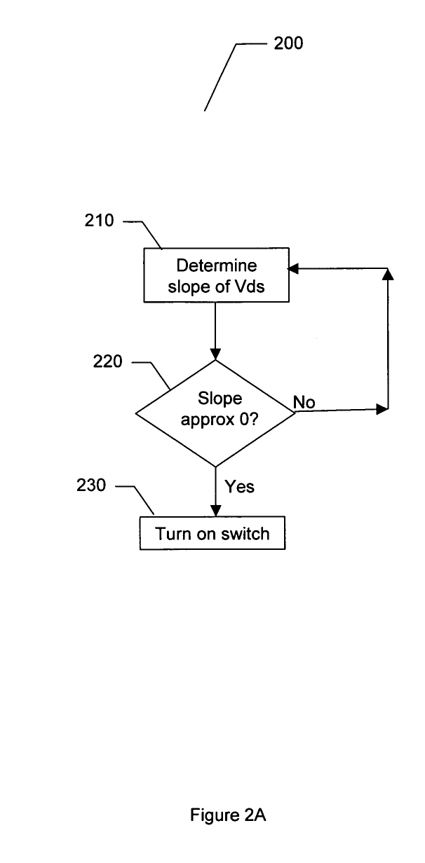

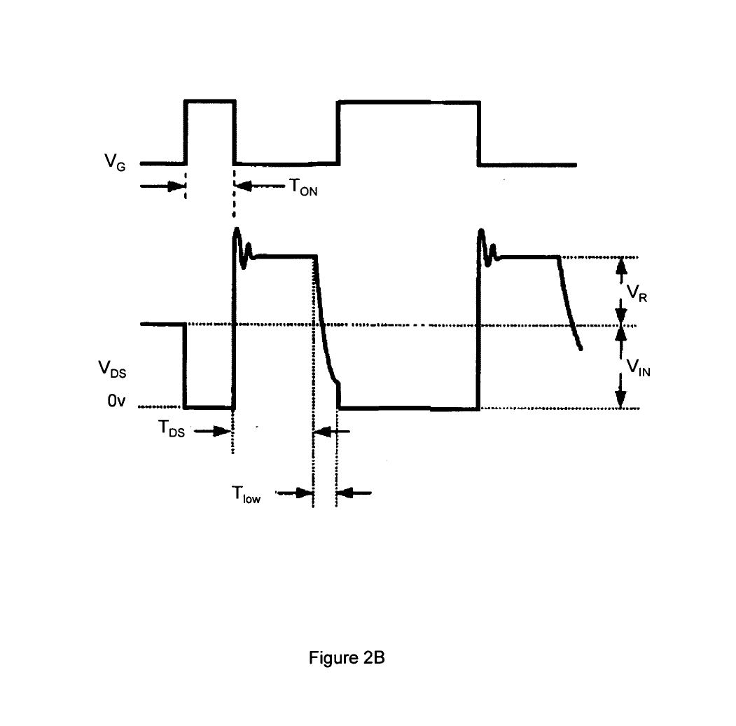

Refer to FIG. 2A, which is a flowchart illustrating a method for reducing switching power loss according to an embodiment of the present invention.

As shown in FIG. 2A the method 200 begins in Step 210 by determining the slope of the V_{DS} voltage. In Step 220 if the slope is approximately equal to zero the switch is turned on in Step 230. If the slope is not approximately equal to zero the method returns to Step 210.

Refer to FIG. 2B, which is a drawing illustrating voltage waveforms resulting from the method of FIG. 2A.

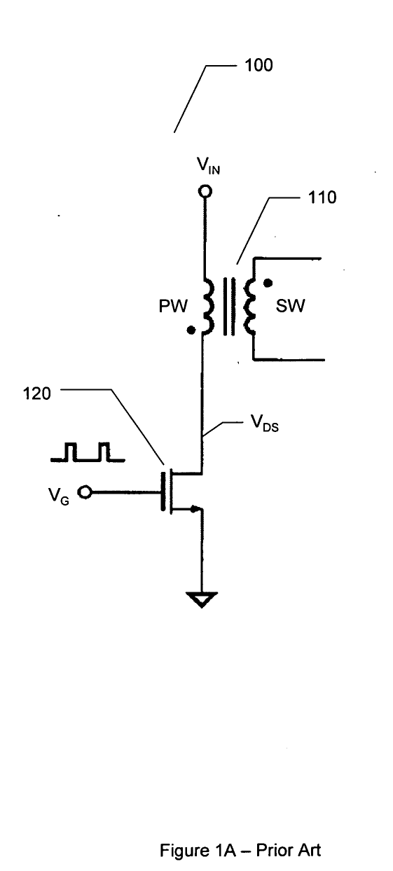

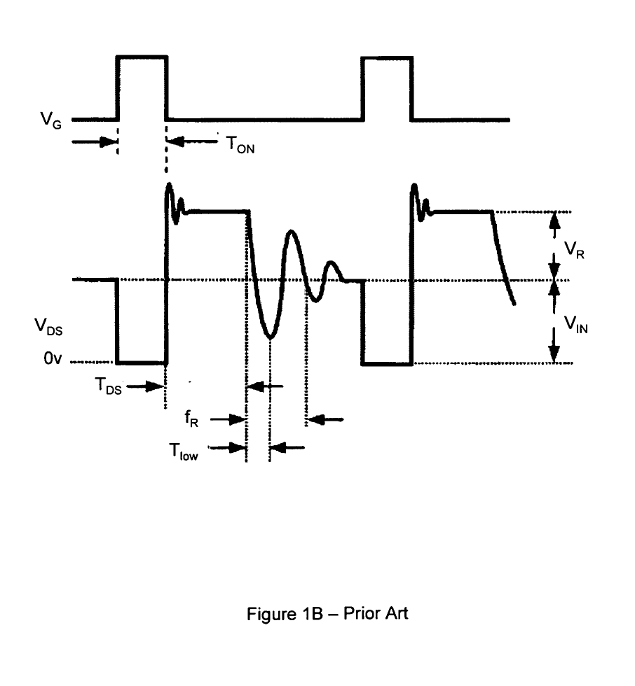

As shown in FIG. 2B the switch is turned on when the voltage level of V_{DS} is close to or at the lowest voltage level. Comparing FIG. 2B to FIG. 1B it is clear to see the reduction in power loss that is achieved by the method of the present invention.

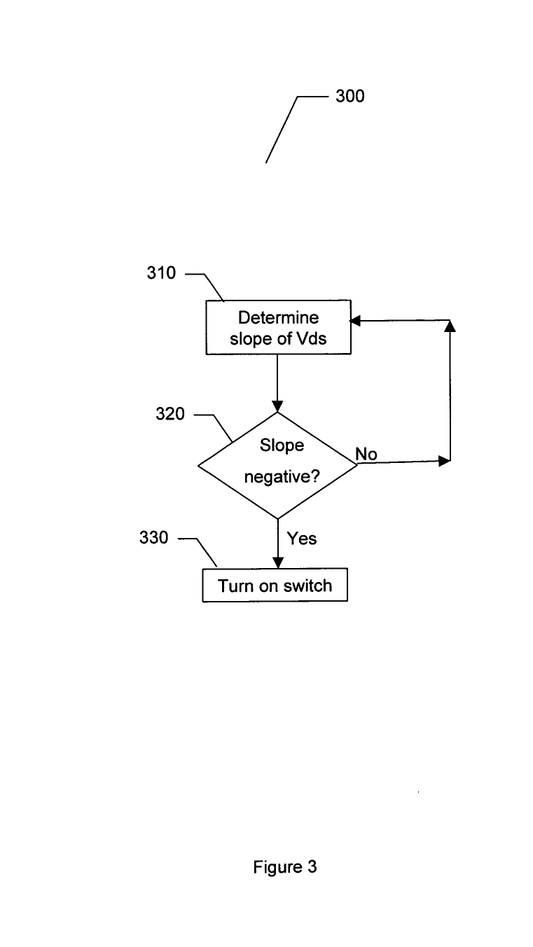

Refer to FIG. 3, which is a flowchart illustrating a method for reducing switching power loss according to an embodiment of the present invention.

As shown in FIG. 3 the method 300 begins in Step 310 by determining the slope of the V_{DS} voltage. In Step 320 if the slope is negative the switch is turned on in Step 330. If the slope is not negative the method returns to Step 310.

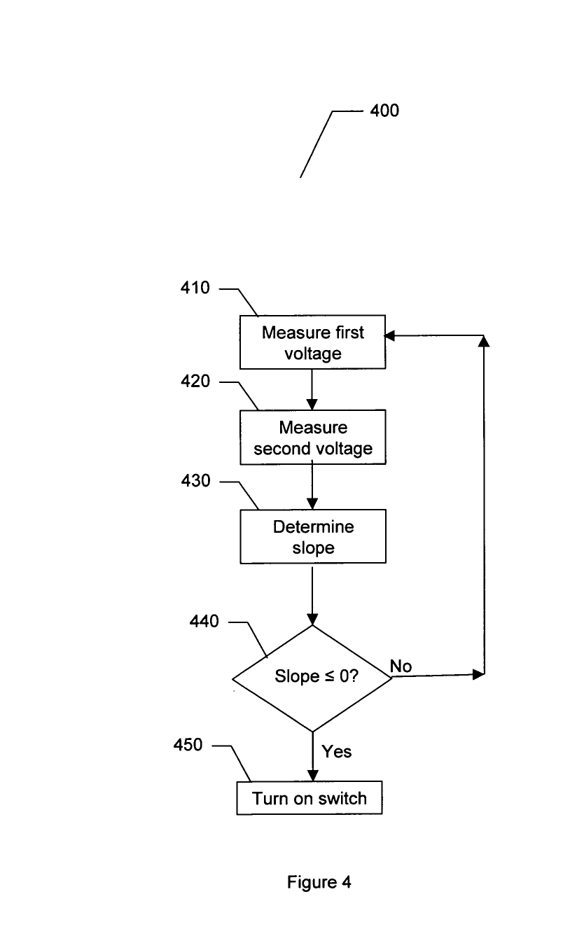

Refer to FIG. 4, which is a flowchart illustrating a method for reducing switching power loss according to an embodiment of the present invention.

As shown in FIG. 4 the method 400 begins in Step 410 by measuring the V_{DS} voltage. The V_{DS} voltage is measured again in Step 420. The slope of the V_{DS} voltage is then determined in Step 430. The slope can be determined using the following equation:

slope=(second voltage measurement−first voltage measurement)/(time of second measurement−time of first measurement)

or

slope=(V_{DS2}−V_{DS1})/(T₂−T₁)

By subtracting the first V_{DS} voltage measurement from the second V_{DS} voltage measurement and dividing by the result of subtracting the time of the first V_{DS} voltage measurement from the time of the second V_{DS} voltage measurement the slope is obtained.

In Step 440 if the slope is negative, another slope is measured. The time duration for the present slope is a percentage of the time duration of the previous slope. In Step 440 if the slope is approximately or equal to zero the switch is turned on in Step 450. If the slope is sufficiently less than zero, another voltage measurement is made and the slope is determined again. This slope is compared with the previous slope that has been stored in a memory. If a slope transition of approximately zero slope is detected, the switch is turned on. If the slope is greater than zero the method returns to Step 410.

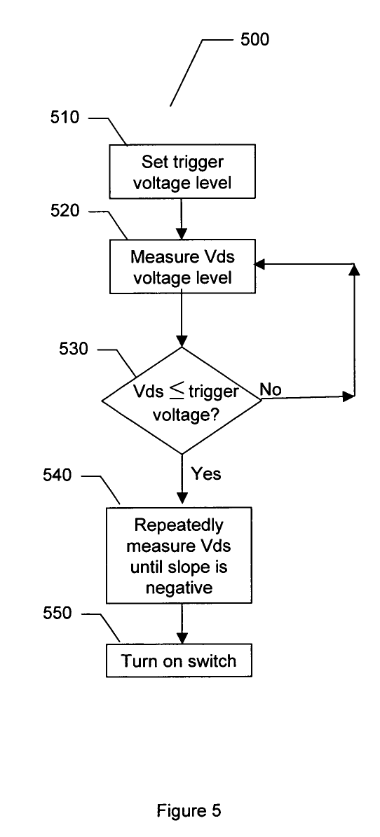

Refer to FIG. 5, which is a flowchart illustrating a method for reducing switching power loss according to an embodiment of the present invention.

As shown in FIG. 5 the method 500 begins in Step 510 by setting a trigger voltage level. The trigger voltage level is a threshold level that the V_{DS} voltage must drop below before proceeding with the rest of the method. In Step 520 the V_{DS} voltage is measured. In Step 530 if the V_{DS} voltage level is greater than the trigger voltage level the method returns to Step 510. If the V_{DS} voltage level is less than or equal to the trigger voltage level the V_{DS} voltage is measured until the slope of the V_{DS} voltage is negative in Step 540. If the slope is negative the switch is turned on in Step 550.

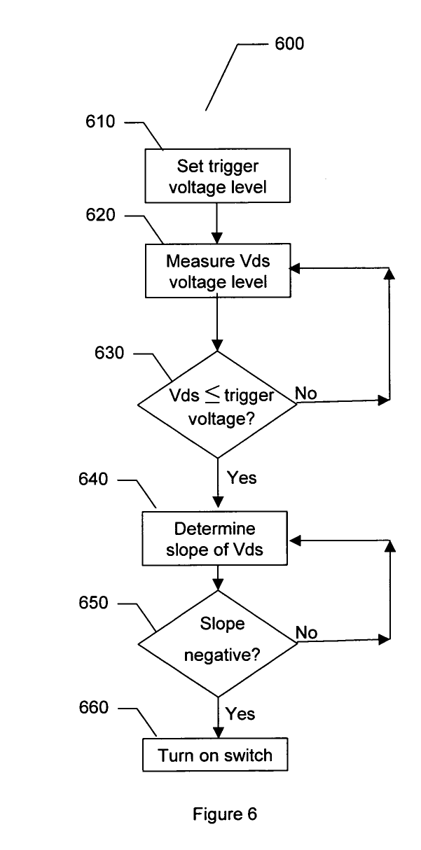

Refer to FIG. 6, which is a flowchart illustrating a method for reducing switching power loss according to an embodiment of the present invention.

As shown in FIG. 6 the method 600 begins in Step 610 by setting a trigger voltage level. In Step 620 the V_{DS} voltage is measured. In Step 630 if the V_{DS} voltage level is greater than the trigger voltage level the method returns to Step 620. If the V_{DS} voltage level is less than or equal to the trigger voltage level the slope of the V_{DS} voltage is determined in Step 640. In Step 650 if the slope is positive the method returns to Step 640 and if the slope is negative the switch is turned on in Step 660.

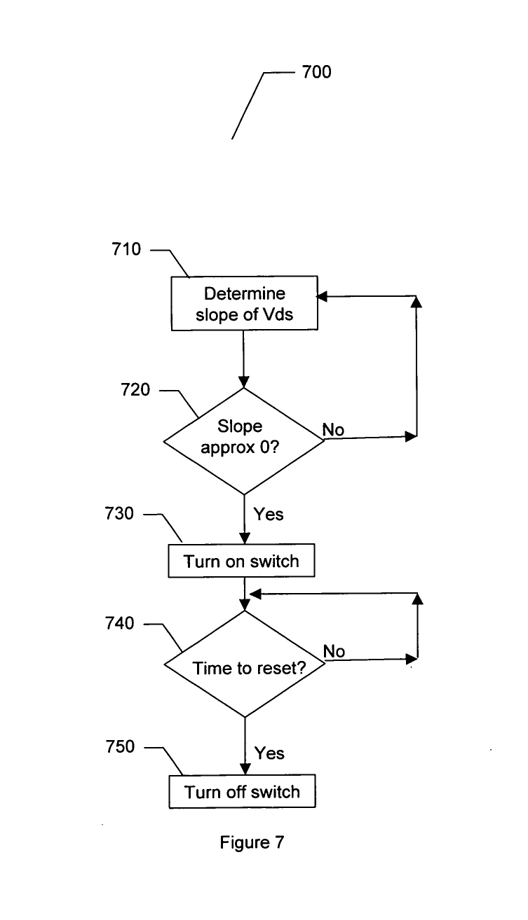

Refer to FIG. 7, which is a flowchart illustrating a method for reducing switching power loss according to an embodiment of the present invention.

As shown in FIG. 7, the method 700 begins in Step 710 determining the slope of the V_{DS} voltage. In Step 720 if the slope is not zero the method returns to Step 710. If the slope is zero the switch is turned on in Step 730. In Step 740 whether or not it is time to reset the switch is determined. The proper reset time can be established by, for example, a predetermined time period, a timer, a signal, or a device in the circuit. When it is time to reset the switch is reset or turned off in Step 750.

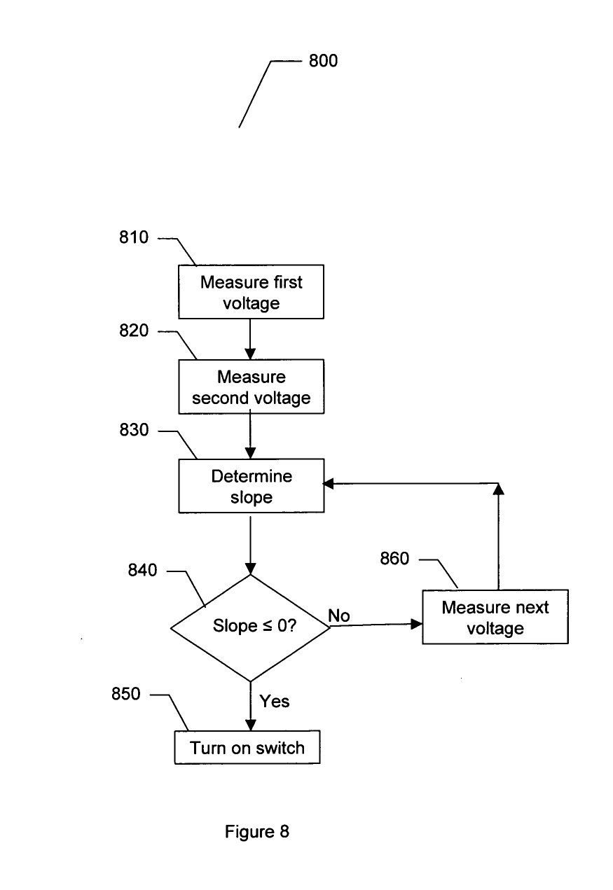

Refer to FIG. 8, which is a flowchart illustrating a method for reducing switching power loss according to an embodiment of the present invention.

The method 800 shown in FIG. 8 begins by measuring the V_{DS} voltage to obtain a first voltage at a first time in Step 810. In Step 820 the V_{DS} voltage is measured again to obtain a second voltage at a second time. In Step 830 the slope is determined. In Step 840 if the slope is less than or equal to zero the switch is turned on in Step 850. If the slope is positive the V_{DS} voltage is measured again in Step 860 and the method returns to Step 830.

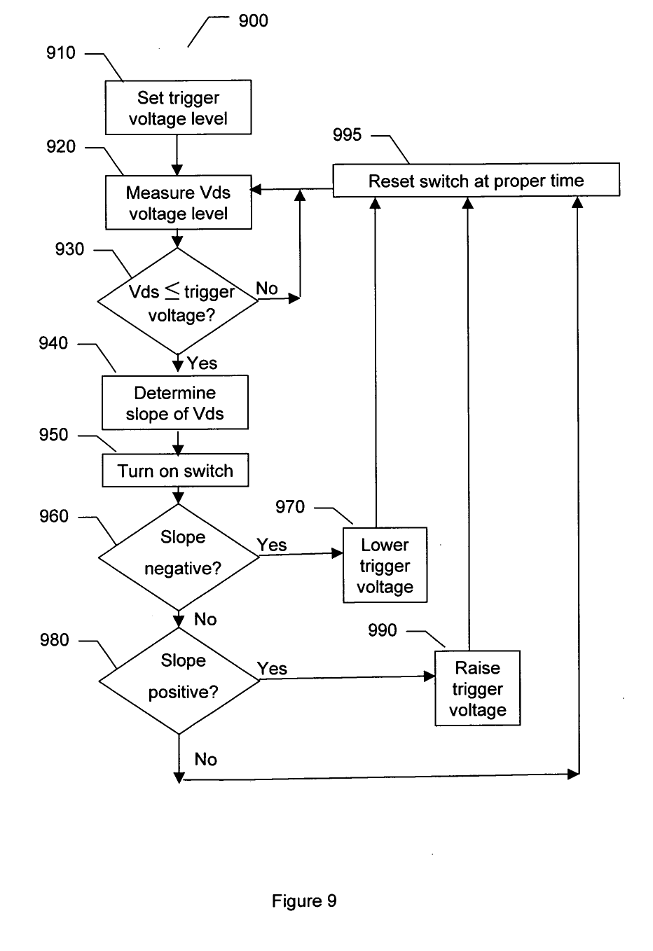

Refer to FIG. 9, which is a flowchart illustrating a method for reducing switching power loss according to an embodiment of the present invention.

As shown in FIG. 9 the method 900 of the present invention begins in Step 910 by setting a trigger voltage level. In Step 920 the V_{DS} voltage level is measured. In Step 930 if the V_{DS} voltage level is not less than or equal to the trigger voltage level the method returns to Step 920. If the V_{DS} voltage level is less than or equal to the trigger voltage level the V_{DS} voltage level is measured again and the slope of the V_{DS} voltage is determined in Step 940. In Step 950 the switch is turned on.

If the slope is negative the trigger voltage level is lowered in Step 970 and the switch is reset in Step 995. In Step 980 if the slope is positive the trigger voltage level is raised in Step 990 and the switch is reset in Step 995. If the slope is equal to zero the trigger voltage level is maintained at its current level and the switch is reset in Step 995. The proper time to reset the switch is determined by, for example, a predetermined time period, a timer, a signal, a reset signal, a circuit, or a device in the circuit. After the switch has completed resetting the method returns to Step 920 and the method continues again.

Since the trigger voltage level is repeatedly adjusted to achieve the closest slope to zero the maximum reduction in power loss is achieved.

In an embodiment of the present invention a minimum trigger voltage level is set to ensure that the trigger voltage level cannot be set too low.

In an embodiment of the present invention a maximum trigger voltage level is set to ensure that the trigger voltage level cannot be set too high.

In embodiments of the present invention the methods illustrated in FIGS. 2-6 and FIG. 8 further comprise steps of resetting the switch.

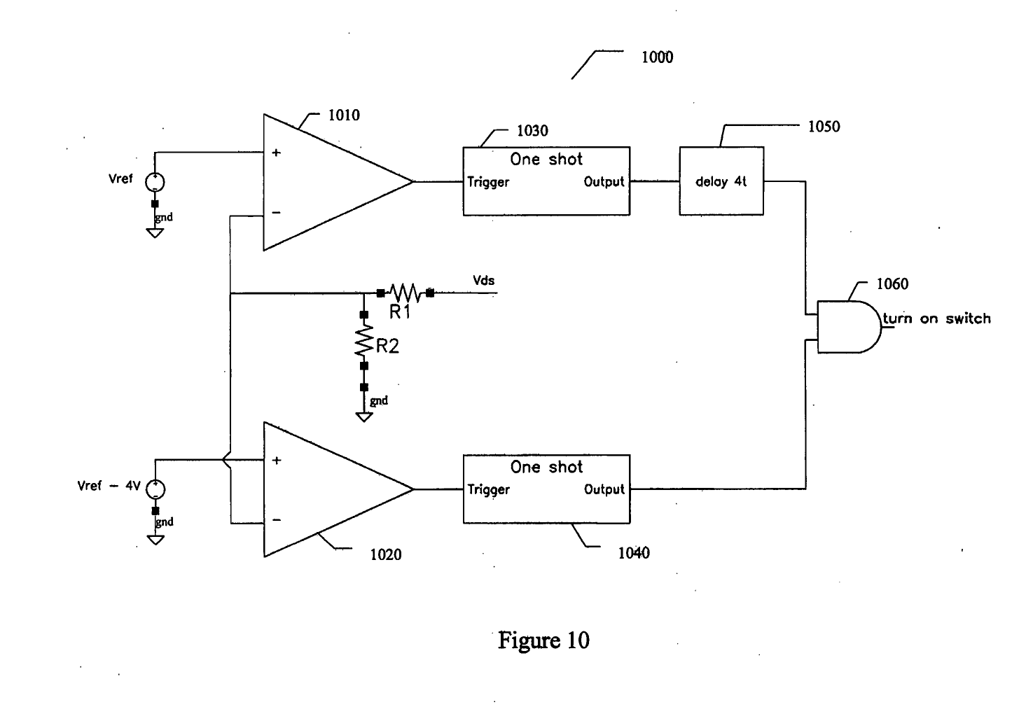

Refer to FIG. 10, which is a diagram illustrating an implementation of a switching power loss reduction method according to an embodiment of the present invention.

In the example circuit 1000 implementation illustrated in FIG. 10 a positive power source Vref is connected to the positive input of a first comparator 1010. A negative power source Vref− is connected to the positive input of a second comparator 1020. The negative inputs of the two comparators 1010 1020 are connected to two resistors R1 R2 the other end of resistor R2 is connected to ground and the other end of resistor R1 is connected to V_{DS}. The output of the first comparator 1010 is connected to a trigger input on a one shot 1030. The output of the one shot 1030 is connected to a delay 1050. The output of the second comparator 1020 is connected to a trigger input of a second one shot 1040. The output of the second one shot 1040 is connected to one input of an AND gate 1060. The output of the delay 1050 is connected to the other input of the AND gate 1060. The output of the AND gate 1060 is connected to the switch. The circuit shown in FIG. 10 allows the switch to be turned on in a manner that reduces switching power loss.

In embodiments of the present invention voltage and slope measurements are not performed when the switch is on and measurement is resumed after the switch is reset.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

What is claimed is:

1. A method for reducing power loss comprising:
determining a slope of a V_{DS} voltage when the V_{DS} voltage is less than or equal to a trigger voltage until the slope of the V_{DS} voltage is negative; and
turning on a switch when the slope becomes negative.

2. The method for reducing power loss of claim 1, further comprising:
turning off the switch after a predetermined period of time.

3. The method for reducing power loss of claim 2, where the method resumes determining slope of the V_{DS} voltage after the switch is turned off.

4. The method for reducing power loss of claim 1, where the slope is determined by:
measuring the V_{DS} voltage to obtain a first voltage level at a first time;
measuring the V_{DS} voltage to obtain a second voltage level at a second time; and
calculating the slope using equation:
slope=(second voltage level−first voltage level)/(second time−first time).

5. The method for reducing power loss of claim 1, further comprising:
lowering the trigger voltage level if the slope is negative.

6. The method for reducing power loss of claim 1, further comprising:
maintaining the trigger voltage level if the slope is zero.

7. The method for reducing power loss of claim 1, further comprising:
raising the trigger voltage if the slope is positive.

8. The method for reducing power loss of claim 1, further comprising:
repeating the method of claim 1 after a predetermined period of time.

9. A method for reducing power loss comprising:
measuring a slope of a V_{DS} voltage; and
turning on a switch when the slope of the V_{DS} voltage becomes zero.

10. The method for reducing power loss of claim 9, further comprising:
measuring the V_{DS} voltage to obtain a first voltage level at a first time;
measuring the V_{DS} voltage to obtain a second voltage at a second time; and
determining the slope of the V_{DS} voltage using equation:
slope=(second voltage level−first voltage level)/(second time−first time).

11. The method for reducing power loss of claim 10, further comprising:
turning off the switch after a predetermined period of time.

12. The method for reducing power loss of claim 11, where the method resumes determining slope of the V_{DS} voltage after the switch is turned off.

13. A method for reducing power loss comprising:
measuring a first voltage level at a first time of a V_{DS} voltage;
measuring a second voltage level at a second time of the V_{DS} voltage;
determining a slope of the V_{DS} voltage; and
turning on a switch when the slope of the V_{DS} voltage is negative.

14. The method for reducing power loss of claim 13, further comprising:
setting a trigger voltage level wherein the first voltage level and the second voltage level are measured when the V_{DS} voltage level is less than the trigger voltage level.

15. The method for reducing power loss of claim 14, further comprising:
lowering the trigger voltage level if the slope is negative.

16. The method for reducing power loss of claim 15, wherein the trigger voltage is lowered by a predetermined amount.

17. The method for reducing power loss of claim 13, where the slope is determined by equation:
slope=(second voltage level−first voltage level)/(second time−first time).

18. The method for reducing power loss of claim 13, further comprising:
turning on the switch when the V_{DS} voltage is less than or equal to the trigger voltage level.

19. The method for reducing power loss of claim 13, further comprising:
turning off the switch after a predetermined period of time.

20. The method for reducing power loss of claim 19, where the method resumes determining slope of the V_{DS} voltage after the switch is turned off.
